(19) United States
(12) Patent Application Publication
(10) Pub. No.: US 2023/0253921 A1
(43) Pub. Date: Aug. 10, 2023

(54) SIGNAL UP-CONVERSION SYSTEM AND METHOD

(71) Applicant: ENTERPRISE CONTROL SYSTEMS LTD, Northamptonshire (GB)

(72) Inventor: Simon HARDING, Northamptonshire (GB)

(21) Appl. No.: 18/003,683

(22) PCT Filed: Jun. 29, 2021
(86) PCT No.: PCT/GB2021/051642

§ 371 Date: Dec. 28, 2022

(30) Foreign Application Priority Data
Jun. 30, 2020 (GB) 2010019.4

(51) Int. Cl. H03D 7/16; H04B 1/04; H03D 7/14

(52) U.S. Cl. CPC H03D 7/165; H04B 1/0475; H03D 7/1466

(57) ABSTRACT

A signal up-conversion system is described. The system comprises a signal input for receiving an input signal to be up-converted; an oscillator system for generating an up-conversion signal having a selectable frequency; a mixer coupled to the input and to the oscillator, for combining the input signal and the up-conversion signal and to generate an up-converted signal; at least two filters, each of the at least two filters having different filtering characteristics; a signal output; a switch system configured to couple one of the at least two filters into a signal path between the output of the mixer and the signal output; and a controller configured to control a frequency of the up-conversion signal and a filter of the at least two filters coupled into the signal path by the switch system. A method switching between up-conversion frequencies is also described.

### TECHNICAL FIELD

The present invention relates to a system and method for generating an up-converted signal.

### BACKGROUND

Up-conversion is the process of shifting a signal to a higher frequency, for example a baseband communication signal can be up-converted to a Radio Frequency (RF) transmission frequency. In some applications, it is required to alter the characteristics of the up-conversion over time. The altered characteristics can include a different up-conversion frequency and/or different filtering of the up-converted signal. Altering the up-conversion characteristics takes time. When the up-conversion characteristics are required to change over a short timescale, equipment capable of sufficiently quick changes can be complex and expensive.

Transmission of wideband time-division multiplexed signals is one area where reducing the time to change up-conversion characteristics is useful. A narrowband signal generator can generate a wideband signal by time-division multiplexing its output with different up-conversion frequencies. While the up-converter is altering the up-conversion characteristics no signal is output, reducing the available time for transmitting signals.

Devices have been proposed which remove up-conversion completely and generate a signal directly at Radio Frequency (RF), ready for transmission. However, some of these devices, such as Software Defined Radio (SDR), have a significant calibration time, preventing rapid changes across a wide band of target frequencies. Other devices require expensive, high specification components such as wideband Digital to Analog Converters (DACs) to provide the required bandwidth and high specification Field Programmable Gate Arrays (FPGAs) to generate the required bitstream for the DAC. Power consumption of such devices is also high, reducing the opportunities for miniaturisation.

It would be desirable to provide an improved up-conversion system.

### SUMMARY

According to a first aspect of the present invention, there is provided a signal up-conversion system. The system comprises: a signal input, an oscillator system, a mixer, at least two filters, a signal output, a switch system and a controller. The signal input is for receiving an input signal to be up-converted. The oscillator system is for generating an up-conversion signal. The mixer is coupled to the input and to the oscillator, and is for combining the input signal and the up-conversion signal to output an up-converted signal. Each of the at least two filters have different filtering characteristics. The signal output is for outputting an up-converted signal. The switch system is configured to couple one of the at least two filters into a signal path between the output of the mixer and the signal output. The controller is configured to control a frequency of the up-conversion signal and a filter of the at least two filters coupled into the signal path by the switch system.

Such a construction allows rapid switching of up-conversion frequency. This is useful for generating a wideband signal from a narrowband signal using time-division multiplexing, for example. The up-conversion system comprises at least two filters which are available to select and have different predetermined filter characteristics, with the switch system allowing quick switches between different filters.

Filter characteristics include at least one of passband, ripple, roll-off, 3 dB point, topology (such as Bessel, Chebyshev, Elliptical). These can be selected, and a suitable filter designed, depending on the desired output profile from the filter. In some examples there may be one filter for a band of up-conversion frequencies and/or signal types, such as a filter for all signals in the band 2.3-2.5 GHz or a filter for Wi-Fi Bands 1 to 11. Other examples may have more than one filter for a band of up-conversion frequencies and/or signal types, so that different filter characteristics can be selected independently of the up-conversion characteristics.

The oscillator system may comprise any suitable frequency source, such as a Phase-Locked-Loop (PLL).

The switch system may comprise relays and microswitches but is preferably solid-state to allow higher speed switching.

In some examples, the oscillator system is configurable from a first to a second frequency in a time less than 30 μs and the switch system is operable to switch from a first to a second of the at least two filters in a time less than 30 μs. This reduces the time spent reconfiguring the up-conversion system (when no useful signal can be output) so that a greater proportion of time is available for outputting a signal. Such rapid switching is useful when transmitting signal across multiple frequencies using time-division multiplexing. Other examples may further reduce these times, for example to less than 20 μs or less than 15 μs. In some examples the time to change the frequency of the oscillator and the time to change the filter is substantially the same, in other examples it may be different.

The controller may be configured to cause the oscillator to change frequency of the up-conversion signal and to cause the switch system to change a filter coupled into the signal path substantially simultaneously. In this way, time taken reconfiguring the up-conversion is minimised by making changes in parallel.

In some examples, the signal up-conversion system comprises a variable attenuator coupled to the signal output, and wherein the controller is configured to cause the variable attenuator to mute the output during a reconfiguration of the up-conversion system. This provides a clean output during reconfiguring the up-conversion (substantially no signal is output) which can reduce damage to subsequent equipment, such as a power amplifier, from transients in the output signal during the reconfiguration. The muting also reduces unwanted signals from being output during reconfiguration, which may provide undesired interference. Muting can be achieved by setting the attenuator to its largest attenuation. Reference to “muting” means that the peak-to-peak voltage of any signal at the output is reduced to a level where the output is small or negligible, for example 10 mV or less.

In other examples, a switch may be associated with the output and operated to achieve muting by coupling or decoupling the signal output from the other components. When the signal output is decoupled it may be grounded.

The signal up-conversion system may further comprise a variable attenuator coupled to the signal output, and wherein the controller is configured to set an output level of an output signal using the variable attenuator. This can allow control over the output level and/or output power from the up-conversion system, perhaps to reduce the possibility of overloading subsequent components such as a power amplifier.

Where the controller is configured to control both output level and output muting using a variable attenuator, these may use the same or different attenuators. Using the same attenuator for both functions can reduce cost and component count.

The oscillator system may comprise: at least two frequency sources, each frequency source operating at a different frequency; and a second switch system configured to couple one of the at least two frequency sources to the mixer. The controller is configured to control the second switch system. Any suitable frequency source may be used, such as a PLL. Having multiple frequency sources allow the up-conversion frequency to be reconfigured more quickly than reconfiguring a single PLL, the speed is effectively limited by the switching speed of the second switch system. As with the switch system for the filters, the second switch system can be any suitable switch system and is preferably solid state for faster switching.

Some examples may include as many frequency sources in the oscillator system as there are up-conversion frequencies, for example if the output signal could be the result of up-conversion to four different frequencies then there are four frequency sources. In other examples, the controller may change the frequency of the frequency sources while they are not in use to a next required frequency. For example, while a first frequency source is being used for up-conversion, a second frequency source could be configured to a next required up-conversion frequency, giving more time for the second frequency source to be configured.

The signal up-conversion system may comprise a control input for receiving a control data, wherein the control data indicates at least one of: required up-conversion parameters; an order for switching between different up-conversion parameters; and timing for switching between different up-conversion parameters. In this way, the up-conversion system can be informed of the required up-conversion parameters. It can allow the signal up-converter to be provided as a module for interface with other components, such as a signal generator generating the input signal for up-conversion.

The up-conversion parameters may comprise at least a required frequency, which may be used by the controller to set the frequency of the oscillator system and choose an appropriate one of the at least two filters. In some examples, the up-conversion parameters may also indicate a particular one of the at least two filters to use for each frequency or required filter characteristics without specifying a particular filter. The up-conversion parameters may also be indicated with reference to a particular standardised band, for example Wi-Fi® channel numbers, cellular telecommunication channel numbers, such as 3G, 4G, LTE or 5G channel numbers, Global Navigation Satellite Systems (GNSS) bands, and so on.

Timing data may indicate a time required for operation with particular up-conversion parameter, such as a time before operation should be changed to a next up-conversion parameter.

In some examples, the control input is a serial input, for example one complying with the RS-485 standard.

A synchronisation input may be provided for receiving an indication that up-conversion parameters are to be changed. Using a synchronisation input can simplify the up-conversion system because the signal up-conversion system need not monitor timings of the changes of the up-conversion parameters itself and can instead respond to the synchronisation signal. For example the synchronisation input may indicate that parameters are to be changed by a voltage pulse, the voltage pulse causing an output of the up-conversion module to be disabled at the start of the pulse and enabled at the end of the pulse, and the up-conversion parameters changed during the pulse. In other examples, the synchronisation input may simply indicate that the up-conversion parameters are to be changed as soon as possible with no further indication of the timing. Some examples may combine the synchronisation input with the control input, allowing both control and synchronisation inputs to be received over the same serial interface.

Some examples may include a protection filter in a signal path after the at least two filters. The protection filter can have characteristics chosen to protect a downstream component connected to the signal up-conversion system, such as a power amplifier. For example, the protection filter may have a pass band chosen to correspond to the operating range of a power amplifier. While the filtering using one of the at least two filters after up-conversion may be sufficient, the protection filter can have, for example a sharper cut off above a maximum operating frequency of a power amplifier to further reduce any unwanted components remaining after the filtering with the at least two filters. In some examples, the protection filter is a low-pass filter with a 3 dB frequency set the maximum operating frequency of power amplifier connected to the signal output.

An attenuator or switch may be provided in the signal path between the oscillator system and the mixer for disconnecting the oscillator from the mixer during a change of oscillator frequency in some examples. This can reduce the presence of transients and spurious mixing products while the oscillator system is reconfigured to a new frequency.

A signal conversion system as discussed above can provide an output bandwidth of at least 4 GHz. The short switching time means that efficient time-division multiplexing of different signals is possible.

According to a second aspect of the invention, there is a provided a method of generating an up-converted signal comprising a time sequence of a plurality of signals at different frequencies, each of the plurality of signals having a respective frequency and a respective filtering characteristic. The method comprises:
for each of the plurality of signals in turn:
   disabling an output;
   while the output is disabled, configuring an oscillator to the respective frequency and establishing the respective filtering characteristic;
   after the configuring and switching is complete, enabling the output;
   receiving an input signal;
   generating an upconverted signal by mixing the input signal with the oscillator and filtering the mixed signal according to the respective filtering characteristic; and
   outputting the upconverted signal.

Such a method allows a time-division multiplexed signal where each signal in the time sequence can have its own frequency. Disabling the output while the oscillator and filtering is configured provides a clean output signal.

The filtering characteristic can be any of the options discussed above for the first aspect, for example a desired passband. The filtering characteristic may be explicitly defined or determined using the frequency and/or another property of the up-conversion, such as a reference to a standardised transmission frequency band.

The method may comprise receiving data indicating the respective frequency of each of the plurality of signals. This can allow the frequencies to be communicated ahead of time, for example to configure oscillators in an oscillator system to those frequencies and allow faster reconfiguration between the frequencies. Some examples may also receive data indicating a respective filtering characteristic.

A switch signal indicating to switch to a next one of the plurality of signals in the time sequence may be received in some examples. In that case, the disabling the output, configuring the frequency and filter, and enabling the output are responsive to the switch signal. This provides a simple way for the up-conversion to be kept in synchrony with a timing of switching between signals in the time sequence of the plurality of signals.

A signal up-conversion system of the first aspect may be configured to perform the method of the second aspect.

According to a third aspect of the invention, there is provided a system comprising: a signal generator; a signal up-conversion system of the first aspect with its signal input coupled to the signal generator; and an amplifier coupled to the output of the signal up-conversion system. The signal generating system is configured to generate the input waveform and provide any control and or/synchronisation signals to the signal up-conversion system.

Such a system may be applied to an RF jamming system which hops between different frequencies using time-division multiplexing to operate over a wider bandwidth than that of an input signal generator. Such a system benefits from increased time transmitting the RF jamming signal because of the short switching time enabled by the up-conversion system. Time division multiplexing can be effective for jamming multiple different communication signals because, after being jammed, it takes time for a target RF system to reacquire the signal. During that time, another RF signal, at a different frequency, can be jammed. A time-division multiplexed system can be simpler and cheaper then generating concurrent jamming signals. Concurrent jamming might require multiple transmission systems. Alternatively, if multiple concurrent signals are combined for input to a single power amplifier, problems with harmonics, intermodulation products and phasing can be introduced. By providing a time-division multiplexed signal, there is no requirement for multiple transmission systems and problems from combining multiple RF jamming signals are not encountered.

Further features and advantages of the invention will become apparent from the following description of preferred embodiments of the invention, given by way of example only, which is made with reference to the accompanying drawings.

### BRIEF DESCRIPTION OF THE DRAWINGS

FIG. 1 is a schematic diagram an example transmission system including a signal upconverter according to an embodiment;

FIG. 2 is a flow diagram of a method for generating an up-converted signal using the signal upconverter of FIG. 1.

### DETAILED DESCRIPTION

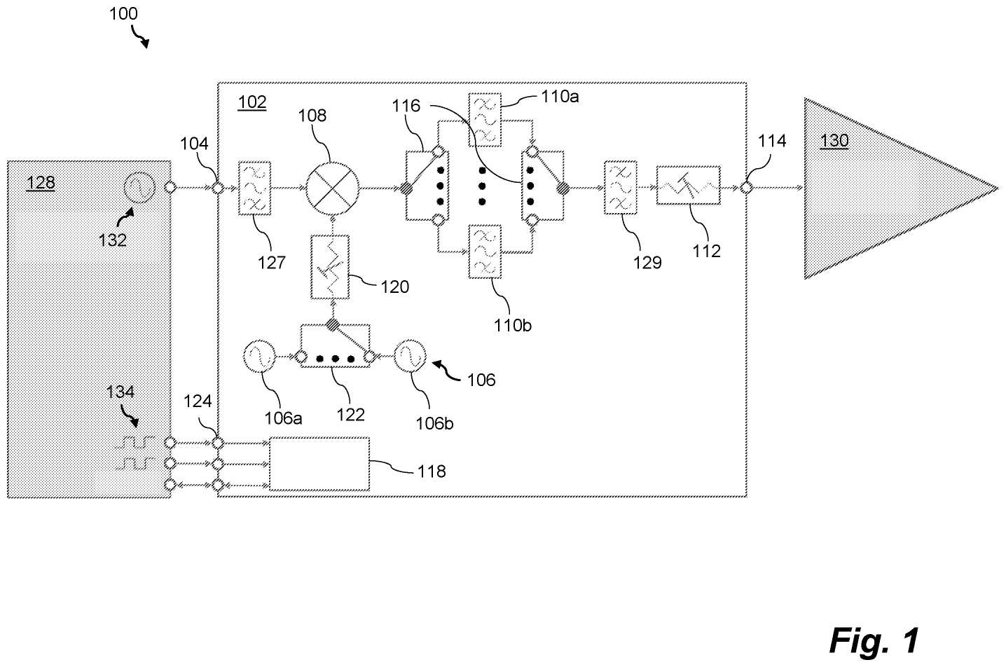

FIG. 1 is a schematic diagram of a transmission system 100, in this case an RF signal jamming system, according to an embodiment. The transmission system 100 comprises a signal up-conversion system 102, a signal generator 128 and an amplifier 130. The signal generator 128 has a bandwidth that is lower than that of the signals desired to be transmitted. In this example, the bandwidth of the signal generator is 1 GHz, in comparison with output signals from the system as a whole of bandwidth 5 GHz or higher. The signal up-conversion system 102 allows rapid switching of up-conversion characteristics, such as frequency, so that the system 100 as a whole operates over a wider bandwidth than the signal generator using time-division multiplexing.

First, the signal up-conversion system will be described. Although described here in the context of a transmission system, the signal up-conversion system can also be used in other systems, without the signal generator 128 and amplifier 130. The signal up-conversion system 102 has an input 104 configured to receive an input waveform 132 and an oscillator system 106 configured to generate an up-conversion signal.

A mixer 108 is coupled to the input 104 via a first protection filter 127. The first protection filter is configured to cut-off frequencies in the input waveform 132 that may cause damage to at least one of the components of the signal up-conversion system 102. In this example, the first protection filter 127 is a band pass filter, which can both remove DC components and frequencies too high for signal up-conversion system 102 to mix reliably. Other examples may use a low pass filter as the protection filter, with a suitable cut-off frequency with reference to a maximum input frequency, such as around 1 GHz.

The mixer is also coupled to the oscillator system 106 and, in use, combines the input waveform 132 and the up-conversion signal to output an up-converted signal. A variable attenuator 120 is coupled between the oscillator system 106 and the mixer 108 to allow disconnection (muting) of the oscillator system 106 from the mixer.

Two filters 110a, 110b are provided in a signal path after the mixer. A switch system 116 comprises first and second switch blocks which are operative to couple one of the two filters 110a, 110b into a signal path after the mixer 108. In use, this means that the output signal from the mixer 108 is filtered by one of the filters 110a, 110b. Filters 110a, 110b have characteristics chosen to match particular up-conversion frequencies or properties (discussed in more detail later).

After filtering, the signal passes through a second protection filter 129, which further filters the signal. The second protection filter 129 has characteristics chosen to reduce the possibility of an output signal having frequency components that could damage later devices, such as the amplifier 130. In this example the second protection filter 129 is a bandpass filter, it can also be a low-pass filter in other examples. Next, the signal passes through a variable attenuator 112 which is coupled to an output 114.

Operation of the oscillator system 106, variable attenuators 120, 112, and switch system 116 is controlled by a controller 118. For clarity, FIG. 1 does not show the control links between the controller 118 and the elements of the signal up-conversion system 102 that it controls. The controller 118 receives configuration data and synchronisation signals 134 from the signal generator 128 via control inputs 124, these include a data input and a synchronisation input.

In the example shown in FIG. 1, two phase-locked loops (PLLs) 106a and 106b are depicted as forming part of the oscillation system 106. These are configured to generate up-conversion signals with respective, different frequencies. Example up-conversion frequencies include a GNSS frequency band, such as L-band frequencies 1184 MHz to 1610 MHz, ISM frequencies (including but not limited to 433.05 MHz to 434.79 MHz, 902-928 MHz, 2.4-2.5 GHz, 5.725-5.875 GHz and 24-24.25 GHz), Wi-Fi (such as around 2.4 GHz, 5 GHz), and cellular communications (bands defined in the GSM, 3G, 4G/LTE and 5G standards). Other examples are possible.

Other examples may have more than two PLLs. Switching between the two different frequencies can be accomplished by operating the switch system 122. The limitation on switching time then becomes the switching speed of the switch system 122, rather than the time taken to reconfigure the PLL from one frequency to another. Any suitable switch system can be used, such as a relay or transistor (solid-state) switch system. In this example, the switch system is the ADRF5020, commercially available from Analog Devices, Inc. The ADRF5020 is a single pole, double throw switch with low insertion loss for signals in the range 100 MHz to 30 GHz and an RF settling time of 15 ns. In use, command signals are sent by the controller 118 to cause the switch system 122 to switch between PLLs.

The switch system 116 is configured to couple one of the filters 110 into a signal path between the mixer 108 and the variable attenuator 112 so that the up-converted signal is filtered by one of the filters 110. In this example the switch system 116 again makes use of the ADRF5020, commercially available from Analog Devices, Inc. One ADRF5020 is used to couple an input of a filter 110 and another ADRF5020 is used to couple an output of the filter 110. In use, command signals from the controller 118 cause the switch system to select an appropriate filter 110.

The filters 110 have different filtering characteristics, which may include different pass bands, ripple, 3 dB frequencies and roll off In this example, the filters 110 are bandpass filters designed to allow frequencies within a particular passband to pass and to attenuate frequencies outside the passband. An appropriate filter is selected based on the up-conversion frequency. For example, a first filter may have a passband of 2-3 GHz and a second filter may have a passband of 5-6 GHz. The first filter is selected when the up-conversion frequency is in the range 2-3 GHz and the second filter is selected when the up-conversion frequency is in the range 5-6 GHz. In other examples, the filters 110a, 110b may be low pass or high pass filters. As well as selecting the filter based on the up-conversion frequency, a filter may also be specified in the control information received by the controller 118.

In use, the signal up-conversion system 102 generates a time-division multiplexed signal by switching the up-conversion frequency output by the oscillator system 106 and an appropriate filter 110a, 110b. When a change of up-conversion frequency and/or filtering is required, the controller mutes the output by increasing the attenuation of the variable attenuator 112 to maximum and mutes the up-conversion signal at the mixer by increasing the attenuation of the variable attenuator 120 to maximum. Meanwhile, the oscillator system 106 is reconfigured to output a different frequency by operating switch system 122, and the switch system 116 is operated to couple a filter with the required filter characteristics into the signal path. Once switching is complete, variable attenuators 112, 120 are unmuted and the up-conversion signal is then operative to up-convert the input signal at the different frequency. This process of muting, switching and unmuting is carried out whenever the up-conversion parameters (frequency and/or filtering) are required change. It can be carried out at sufficient speeds to minimise the time that the output spends muted, for example reconfiguration may be completed in as short a time as 12 μs or less.

The input signal or waveform 132 supplied to the signal up-conversion system 102 is generated by the signal generator 128 and received at the input 104. An example signal generator is that used in the ADDS® system commercially available from Blighter Surveillance Systems Ltd, UK, Chess Dynamics Ltd, UK and Enterprise Control Systems Ltd, UK, which generates a waveform that can jam RF communication signals, such as a noise signal targeted at the RF communication system to jam. The signal generator generates baseband or intermediate frequency (IF) waveforms which are required to be up-converted to a transmission frequency. A bandwidth of the input signal is narrow relative to the output of the system as a whole, for example a jamming signal may have an instantaneous bandwidth of 1 GHz. The signal up-conversion system 102 can up-convert such signals in an agile and cost-effective manner allowing the transmission system 100 to have an effective bandwidth of 5 GHz or higher through the use of time-division multiplexing.

Control signals 134 from the signal generator 128 are received via the control inputs 124 at the signal up-conversion system 102. These control systems contain data of up-conversion frequencies and associated filtering characteristics, together with a sequence in which the frequencies should be changed. Based on the received control signals 134, the controller 118 controls the operation of the variable attenuators 112, 120, the switch system 116 and the oscillator system 106. In this example, a synchronisation signal is supplied by the signal generator through input 124 when reconfiguring up-conversion parameters to the next set in the sequence is required. In other examples, the control signals 134 may include timing information indicating to the controller 118 when to reconfigure the up-conversion parameters, such as a predetermined timing for operation at one frequency before reconfiguring to another frequency.

The output 114 is provided to the power amplifier 130 to be amplified for transmission. The same power amplifier is used for all up-converted signals and the operating frequency range of the power amplifier therefore includes all the up-conversion frequencies that can be generated by the up-conversion system. For example, the power amplifier may have a bandwidth of at least 6 GHz or more.

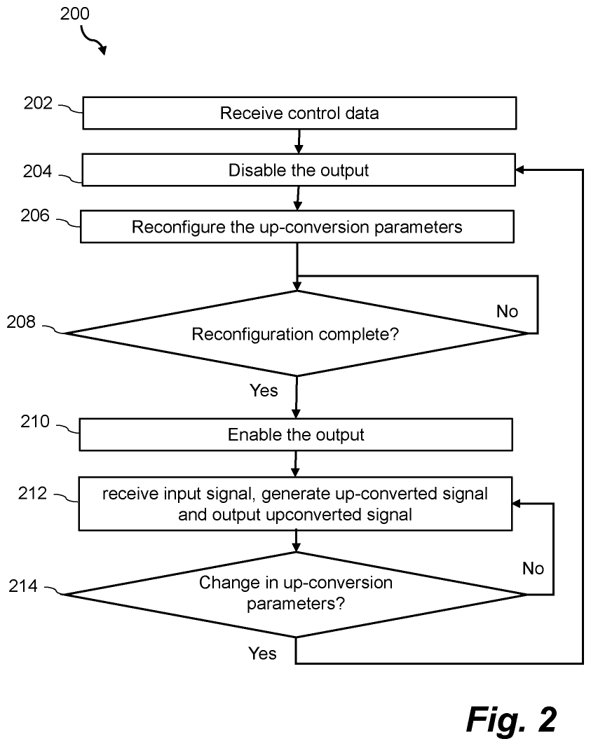

A method 200 of generating a signal comprising a plurality of time-division multiplexed components using the signal up-conversion system 102 will now be described with reference to FIG. 2.

At block 202, control data is received. The control data indicates the up-conversion parameters, such as frequency and a sequence for changing the frequency. The controller 118 uses the control data to initialise the oscillator system 106 with frequencies indicated in the control data.

Next, at block 204, an output 114 of the signal up-conversion system 102 is disabled. For example, this may involve setting the attenuation of the variable attenuator 112 to maximum.

While the output is disabled, the up-conversion parameters indicated in the control data are reconfigured at block 206. For example, the switch systems 116 and 122 are operated to select a frequency source and filter matching the up-conversion parameters. At block 208, it is determined whether the reconfiguration is complete. This could be based on known timings for reconfiguration (such as a maximum time for switching). When it is determined that reconfiguration is complete, the output 114 is enabled at block 210 by reducing the attenuation of the variable attenuator 112.

The up-conversion system is then operative to receive an input signal which is upconverted, filtered and output at block 212. This continues until a change in up-conversion parameters is determined at block 214. The change may be determined in block 214 by receipt of a control signal to change or by a predetermined time elapsing. When a change is required the method returns to block 204 and repeats blocks 204, 206, 208, 210 and 212 for the next set of up-conversion parameters, such as the next set of parameters in the sequence indicated by the control data received at block 202.

In this way, up-conversion parameters can be changed quickly to minimise downtime when switching between frequencies to generate a time division multiplexed signal comprising signals of different frequencies.

The above embodiments are to be understood as illustrative examples of the invention. Further embodiments of the invention are envisaged. For example, the system of FIG. 1 can be provided with more than two filters 110 and more than two PLLs 106. In that case switch systems with more throws can be used, such as single pole, four throw switch to support four filters or PLLs. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

1. A signal up-conversion system comprising:
a signal input for receiving an input signal to be up-converted;
an oscillator system for generating an up-conversion signal;
a mixer coupled to the input and to the oscillator, for combining the input signal and the up-conversion signal to output an up-converted signal;
at least two filters, each of the at least two filters having different filtering characteristics;
a signal output for outputting an up-converted signal;
a switch system configured to couple one of the at least two filters into a signal path between the output of the mixer and the signal output; and
a controller configured to control a frequency of the up-conversion signal and a filter of the at least two filters coupled into the signal path by the switch system.

2. A signal up-conversion system according to claim 1, wherein the oscillator system is configurable from a first to a second frequency in a time less than 30 μs and the switch system is operable to switch from a first to a second of the at least two filters in a time less than 30 μs.

3. A signal up-conversion system according to claim 1 or 2, wherein the controller is configured to cause the oscillator to change the frequency of the up-conversion signal and to cause the switch system to change a filter coupled into the signal path substantially simultaneously.

4. A signal up-conversion system according to any preceding claim, further comprising a variable attenuator coupled to the signal output, and wherein the controller is configured to cause the variable attenuator to mute the output during a reconfiguration of the up-conversion system.

5. A signal up-conversion system according to any preceding claim, further comprising a variable attenuator coupled to the signal output, and wherein the controller is configured to set an output level of the upconverted signal using the variable attenuator.

6. A signal up-conversion system according to any preceding claim, wherein the oscillator system comprises:
at least two frequency sources, each frequency source operating at a different frequency; and
a second switch system configured to couple one of the at least two frequency sources to the mixer;
wherein the controller is configured to control the second switch system.

7. A signal up-conversion system according to any preceding claim, comprising a control input for receiving control data, wherein the control data indicates at least one of:
required up-conversion parameters;
an order for switching between different up-conversion parameters; and
timing for switching between different up-conversion parameters.

8. A signal up-conversion system according to any preceding claim, comprising a synchronisation input for receiving an indication that up-conversion parameters are to be changed.

9. A signal up-conversion system according to any preceding claim comprising a protection filter in a signal path after the at least two filters.

10. A signal up-conversion system according to any preceding claim, comprising an attenuator or switch between the oscillator and the mixer for disconnecting the oscillator from the mixer during a change of oscillator frequency.

11. A method of generating an up-converted signal comprising a time sequence of a plurality of signals at different frequencies, each of the plurality of signals having a respective frequency and a respective filtering characteristic, the method comprising:
for each of the plurality of signals in turn:
disabling an output;
while the output is disabled, configuring an oscillator to the respective frequency and establishing the respective filtering characteristic;
after the configuring and switching is complete, enabling the output;
receiving an input signal;
generating an upconverted signal by mixing the input signal with the oscillator and filtering the mixed signal according to the respective filtering characteristic;
outputting the upconverted signal.

12. A method according to claim 11, comprising:
receiving data indicating the respective frequency of each of the plurality of signals.

13. A method according to claim 11 or 12, comprising:
receiving a switch signal indicating to switch to a next one of the plurality of signals in the time sequence; and
wherein the disabling the output, configuring the frequency and filter, and enabling the output are responsive to the switch signal.

14. A signal up-conversion system of any of claims 1 to 10 configured to perform the method of any of claims 11 to 13.

15. A system comprising:
a signal generator;
a signal up-conversion system according to any of claims 1 to 10 with its signal input coupled to the signal generator; and
an amplifier coupled to the output of the signal up-conversion system;
wherein the signal generating system is configured to generate the input waveform and provide any control and/or synchronisation signals to the signal up-conversion system.
